(19) United States
(12) Patent Application Publication
(10) Pub. No.: US 2018/0083215 A1
(43) Pub. Date: Mar. 22, 2018

(54) ELECTROLUMINESCENCE AND PHOTOLUMINESCENCE MIXED DISPLAY ELEMENT AND MANUFACTURE METHOD THEREOF

(71) Applicant: Shenzhen China Star Optoelectronics Technology Co., Ltd., Shenzhen City (CN)

(72) Inventor: Yanan Wang, Shenzhen City (CN)

(21) Appl. No.: 15/106,831

(22) PCT Filed: Apr. 27, 2016
(86) PCT No.: PCT/CN2016/080328

§ 371 Date: Jun. 21, 2016

(30) Foreign Application Priority Data
Apr. 7, 2016 (CN) 201610212749.1

(51) Int. Cl. H01L 51/50; H01L 51/52; H01L 27/32; H01L 51/56

(52) U.S. Cl. CPC H01L 51/502; H01L 51/5206; H01L 51/5221; H01L 51/5271; H01L 51/5088; H01L 2251/558; H01L 51/5072; H01L 51/5284; H01L 27/322; H01L 51/56; H01L 51/5056

(57) ABSTRACT

The electroluminescence and photoluminescence mixed display element of the present invention comprises: a light guide substrate (10), a light emitting layer (20) located on the light guide substrate (10), a light filtering layer (30) located on the light emitting layer, wherein the light emitting layer (20) comprises an electroluminescence layer (21) and a photoluminescence layer (22), and the cathode of the electroluminescence layer (21) is a transflective electrode, and the anode is a transparent electrode, and the electroluminescence layer (21) can illuminate the blue light from two sides, the cathode and the anode, and the blue light illuminated from the anode is directionally guided by the light guide substrate (10) and is reflected onto the photoluminescence layer (22) to excite the photoluminescence layer (22) emit the red light and the green light, and the red light and the green light and the blue light are mixed to form white light.

### FIELD OF THE INVENTION

The present invention relates to a display technology field, and more particularly to an electroluminescence and photoluminescence mixed display element and a manufacture method thereof.

### BACKGROUND OF THE INVENTION

The Organic Light Emitting Diodes (OLED) display device possesses many outstanding properties of self-illumination, low driving voltage, high luminescence efficiency, short response time, high clarity and contrast, near 180° view angle, wide range of working temperature, applicability of flexible display and large scale full color display. The OLED is considered as the most potential display device.

The OLED display element is a self-emitting type display device, and generally comprises a pixel electrode and a common electrode respectively employed as being the anode and the cathode, and an organic light emitting layer positioned between the pixel electrode and the common electrode. As the proper voltages are applied to the anode and the cathode, the organic light emitting layer emits light. The organic light emitting layer comprises a Hole Injection Layer positioned on the anode, a Hole Transporting Layer positioned on the Hole Injection Layer, a light emitting layer positioned on the Hole Transporting Layer, an Electron Transport Layer positioned on the light emitting layer and an Electron Injection Layer positioned on the Electron Transport Layer. The lighting principle is that under certain voltage driving, the Electron and the Hole are respectively injected into the Electron Injection Layer and Hole Electron Injection Layer from the cathode and the anode. The Electron and the Hole respectively migrate from the Electron Transporting Layer and Hole Transporting Layer to the Emitting layer and bump into each other in the Emitting layer to form an exciton to excite the emitting molecule. The latter can illuminate after the radiative relaxation.

The Quantumdots (QDs) light emitting material is a new technology applied in the display technology field. The Quantumdots light emitting material obeys the quantum size effect, and the properties change along with the size change of the quantum dots. As being stimulated by the light or the electricity, the quantum dots emit the colored light. The color of the light is related with the property. Thus, the emitted light can be controlled by changing the size thereof. The Quantumdots light emitting material possesses advantages of luminescence spectrum concentration and high color purity. While the Quantumdots light emitting material is employed in the display technology field, the gamut of the traditional display can be tremendously promoted to enhance the color reduction ability of the display.

Please refer to FIG. 1, which is a structure diagram of an electroluminescence element according to prior art, comprising a transparent substrate 100, an anode 200, a hole injecting layer 300, a hole transporting layer 400, an electroluminescence layer 500, an emission layer 600 and a cathode 700, which are stacked up from bottom to top in sequence on the substrate 100, wherein the anode 200 is a transparent electrode, and the cathode 700 is a reflective electrode. When the certain drive voltages are applied to the anode 200 and the cathode 700, and the electron and the hole are respectively injected from the cathode 700 and the anode 200 into the emission layer 600 and the hole transporting layer 400, and then migrate to the electroluminescence layer 500, and meet and combine to be excited to emit light in the electroluminescence layer 500. The light emitted by the electroluminescence layer 500 partially illuminates to the anode 200, and partially illuminates to the cathode 700, and is reflected toward the anode 200, and finally, the transparent substrate 100 illuminates the light out of the electroluminescence element. Because the light emitted by the electroluminescence layer 500 has no specific illuminating direction, the light illuminating to the cathode 700 will pass through many film structures, and the light efficiency is low.

### SUMMARY OF THE INVENTION

An objective of the present invention is to provide an electroluminescence and photoluminescence mixed display element, which possesses high light efficiency and high display gamut, and the color reduction ability is strong to have higher product quality.

Another objective of the present invention is to provide a manufacture method of an electroluminescence and photoluminescence mixed display element, which can raise the light efficiency, and raise the color gamut of the display element, and increase the color reduction ability to promote the product quality.

For realizing the aforesaid objectives, the present invention first provides an electroluminescence and photoluminescence mixed display element, comprising a light guide substrate, and a plurality of sub pixels aligned in array on the light guide substrate;

each sub pixel comprises: a light emitting layer located on the light guide substrate, and a light filtering layer located on the light emitting layer;

a lower substrate of the light guide substrate is formed with a plurality of grooves extending along a short side direction of the sub pixel, and transversal cross sections of the plurality of grooves appear to be aligned in an zigzag, and the lower surface of the light guide substrate is coated with a reflective film;

the light emitting layer comprises: an electroluminescence layer and a photoluminescence layer located at two sides of the electroluminescence layer;

the electroluminescence layer comprises: an anode located on the light guide substrate, a blue light emitting layer located on the anode, and a cathode located on the blue light emitting layer;

the anode is a transparent electrode, and the cathode is a transflective electrode;

the photoluminescence layer comprises red quantum dots material and green quantum dots material;

blue light emitted by the electroluminescence layer is respectively illuminated through two directions of the anode and the cathode, and the blue light illuminated through the anode is reflected by the light guide substrate onto the photoluminescence layer to excite the photoluminescence layer to emit red light and green light, and red light and the green light emitted by the photoluminescence layer and the blue light emitted by the electroluminescence layer are mixed to form white light, and the white light is filtered by the light filtering layer to achieve color display.

The blue light emitting layer is an OLED light emitting layer or a QLED light emitting layer;

the blue light emitting layer comprises: a hole injecting layer located on the anode, a hole transporting layer located on the hole injecting layer, an emission layer located on the hole injecting layer, and an electron transporting layer located on the emission layer.

The cathode is a metal silver thin layer, a graphene transparent conductive film or a metal nano mesh structure.

The light emitting layer further comprises a photoluminescence layer located at a top of the electroluminescence layer, and a film thickness of the photoluminescence layer located at a top of the electroluminescence layer is smaller than a film thickness of the photoluminescence layer located at the two sides of the electroluminescence layer;

a flat layer is further located between the light emitting layer and the light filtering layer.

The light filtering layer comprises: a red filter layer, a blue filter layer and a green filter layer, and each sub pixel corresponds to a light filtering layer of one color, and three sub pixels corresponding to the light filtering layers of three colors construct one display pixel;

a black matrix is located among the light filtering layers of adjacent sub pixels.

The present invention further comprises a manufacture method of an electroluminescence and photoluminescence mixed display element, comprising steps of:

step 1, providing a substrate, and forming a plurality of grooves extending along the same direction on a lower substrate of the substrate, and transversal cross sections of the plurality of grooves appear to be aligned in an zigzag, and the lower surface of the light guide substrate is coated with a reflective film to form a light guide substrate;

step 2, dividing the light guide substrate into a plurality of sub pixel regions aligned in array, and a short side direction of the sub pixel region and an extension direction of the grooves are the same, and forming a light emitting layer on the respective sub pixel regions;

the light emitting layer comprises: an electroluminescence layer and a photoluminescence layer located at two sides of the electroluminescence layer, which are sequentially formed;

the electroluminescence layer comprises: an anode located on the light guide substrate, a blue light emitting layer located on the anode, and a cathode located on the blue light emitting layer;

the anode is a transparent electrode, and the cathode is a transflective electrode;

the photoluminescence layer comprises red quantum dots material and green quantum dots material;

step 3, forming a light filtering layer on the light emitting layer, and forming a plurality of sub pixels aligned in array on the light guide substrate to manufacture the electroluminescence and photoluminescence mixed display element;

blue light emitted by the electroluminescence layer is respectively illuminated through two directions of the anode and the cathode, and the blue light illuminated through the anode is reflected by the light guide substrate onto the photoluminescence layer to excite the photoluminescence layer to emit red light and green light, and red light and the green light emitted by the photoluminescence layer and the blue light emitted by the electroluminescence layer are mixed to form white light, and the white light is filtered by the light filtering layer to achieve color display.

The blue light emitting layer is an OLED light emitting layer or a QLED light emitting layer;

the blue light emitting layer comprises: a hole injecting layer located on the anode, a hole transporting layer located on the hole injecting layer, an emission layer located on the hole injecting layer, and an electron transporting layer located on the emission layer.

The step 2 comprises: first, forming the electroluminescence layer on the light guide substrate, and then, forming the photoluminescence layer at two sides of the electroluminescence layer by a method of coating specific regions.

The step 2 comprises: first, forming the electroluminescence layer on the light guide substrate, and then, forming the photoluminescence layers at the two sides and a top of the electroluminescence layer by a method of full coating, and a film thickness of the photoluminescence layer located at a top of the electroluminescence layer is smaller than a film thickness of the photoluminescence layer located at the two sides of the electroluminescence layer, and then, forming a flat layer on the light emitting layer.

The light filtering layer comprises: a red filter layer, a blue filter layer and a green filter layer, and each sub pixel corresponds to a light filtering layer of one color, and three sub pixels corresponding to the light filtering layers of three colors construct one display pixel;

a black matrix is located among the light filtering layers of adjacent sub pixels.

The present invention further provides an electroluminescence and photoluminescence mixed display element, comprising a light guide substrate, and a plurality of sub pixels aligned in array on the light guide substrate;

each sub pixel comprises: a light emitting layer located on the light guide substrate, and a light filtering layer located on the light emitting layer;

a lower substrate of the light guide substrate is formed with a plurality of grooves extending along a short side direction of the sub pixel, and transversal cross sections of the plurality of grooves appear to be aligned in an zigzag, and the lower surface of the light guide substrate is coated with a reflective film;

the light emitting layer comprises: an electroluminescence layer and a photoluminescence layer located at two sides of the electroluminescence layer;

the electroluminescence layer comprises: an anode located on the light guide substrate, a blue light emitting layer located on the anode, and a cathode located on the blue light emitting layer;

the anode is a transparent electrode, and the cathode is a transflective electrode;

the photoluminescence layer comprises red quantum dots material and green quantum dots material;

blue light emitted by the electroluminescence layer is respectively illuminated through two directions of the anode and the cathode, and the blue light illuminated through the anode is reflected by the light guide substrate onto the photoluminescence layer to excite the photoluminescence layer to emit red light and green light, and red light and the green light emitted by the photoluminescence layer and the blue light emitted by the electroluminescence layer are mixed to form white light, and the white light is filtered by the light filtering layer to achieve color display;

wherein the blue light emitting layer is an OLED light emitting layer or a QLED light emitting layer;

the blue light emitting layer comprises: a hole injecting layer located on the anode, a hole transporting layer located on the hole injecting layer, an emission layer located on the hole injecting layer, and an electron transporting layer located on the emission layer;

wherein the cathode is a metal silver thin layer, a graphene transparent conductive film or a metal nano mesh structure.

The benefits of the present invention are: the electroluminescence and photoluminescence mixed display element provided by the present invention comprises: a light guide substrate, a light emitting layer located on the light guide substrate, a light filtering layer located on the light emitting layer, wherein the light emitting layer comprises an electroluminescence layer and a photoluminescence layer, and the cathode of the electroluminescence layer is a transflective electrode, and the anode is a transparent electrode, and the electroluminescence layer can illuminates the blue light from two sides, the cathode and the anode, and the blue light illuminated from the anode is directionally guided by the light guide substrate and is reflected onto the photoluminescence layer to excite the photoluminescence layer emit the red light and the green light, and the red light and the green light emitted by the photoluminescence layer and the blue light emitted by the electroluminescence layer are mixed to form white light, and the white light is filtered by the light filtering layer to achieve color display, which can raise the light efficiency, and raise the color gamut of the display element, and increase the color reduction ability to promote the product quality. The present invention further provides a manufacture method of an electroluminescence and photoluminescence mixed display element, which can raise the light efficiency, and raise the color gamut of the display element, and increase the color reduction ability to promote the product quality.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a structure diagram of an electroluminescence element according to prior art;

FIG. 2 is a structure diagram of an electroluminescence and photoluminescence mixed display element according to the first embodiment of the present invention;

FIG. 3 is a structure diagram of an electroluminescence and photoluminescence mixed display element according to the second embodiment of the present invention;

FIG. 4 is a structure diagram of a light guide substrate in an electroluminescence and photoluminescence mixed display element of the present invention;

FIG. 5 is a structure diagram of an electroluminescence layer in an electroluminescence and photoluminescence mixed display element of the present invention;

FIG. 6 is a flowchart of a manufacture method of an electroluminescence and photoluminescence mixed display element according to the present invention;

FIG. 7 is a diagram as manufacturing an electroluminescence layer in the step 2 in a manufacture method of an electroluminescence and photoluminescence mixed display element according to the present invention;

FIG. 8 is a diagram as manufacturing a light emitting layer in the step 2 in a manufacture method of an electroluminescence and photoluminescence mixed display element according to the first embodiment of the present invention;

FIG. 9 is a diagram as manufacturing a light emitting layer in the step 2 in a manufacture method of an electroluminescence and photoluminescence mixed display element according to the second embodiment of the present invention;

FIG. 10 is a diagram of the step 3 in a manufacture method of an electroluminescence and photoluminescence mixed display element according to the first embodiment of the present invention;

FIG. 11 is a diagram of the step 3 in a manufacture method of an electroluminescence and photoluminescence mixed display element according to the second embodiment of the present invention.

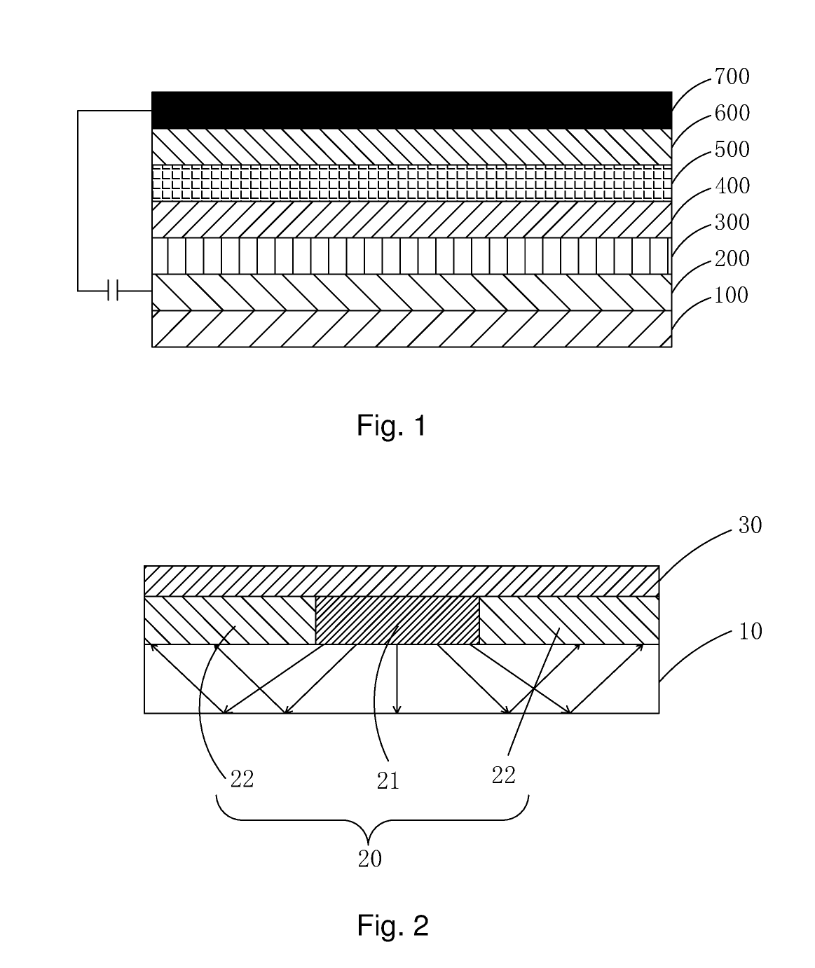

### DETAILED DESCRIPTION OF PREFERRED EMBODIMENTS

For better explaining the technical solution and the effect of the present invention, the present invention will be further described in detail with the accompanying drawings and the specific embodiments.

Please refer to FIG. 2 with combination of FIG. 4. FIG. 2 is the first embodiment of the electroluminescence and photoluminescence mixed display element of the present invention. The electroluminescence and photoluminescence mixed display element comprises: a light guide substrate 10, and a plurality of sub pixels aligned in array on the light guide substrate 10;

each sub pixel comprises: a light emitting layer 20 located on the light guide substrate 10, and a light filtering layer 30 located on the light emitting layer 20;

a lower substrate of the light guide substrate 10 is formed with a plurality of grooves 11 extending along a short side direction of the sub pixel, and transversal cross sections of the plurality of grooves 11 appear to be aligned in an zigzag, and the lower surface of the light guide substrate 10 is coated with a reflective film;

the light emitting layer 20 comprises: an electroluminescence layer 21 and a photoluminescence layer 22 located at two sides of the electroluminescence layer 21;

the electroluminescence layer 21 comprises: an anode 211 located on the light guide substrate 10, a blue light emitting layer 212 located on the anode 211, and a cathode 213 located on the blue light emitting layer 212;

the anode 211 is a transparent electrode, and the cathode 213 is a transflective electrode;

the photoluminescence layer 22 comprises red quantum dots material and green quantum dots material.

Specifically, the color display process of the electroluminescence and photoluminescence mixed display element is: the drive voltage is applied to the electroluminescence layer 21 to excite the electroluminescence layer 21 to emit the blue light, and the blue light emitted by the electroluminescence layer 21 is respectively illuminated through two directions of the anode 211 and the cathode 213, and the blue light illuminated through the anode 211 is reflected by the light guide substrate 10 onto the photoluminescence layer 22 to excite the photoluminescence layer 22 to emit red light and green light, and red light and the green light emitted by the photoluminescence layer 22 and the blue light emitted by the electroluminescence layer 21 are mixed to form white light, and the white light is filtered by the light filtering 30 to achieve color display.

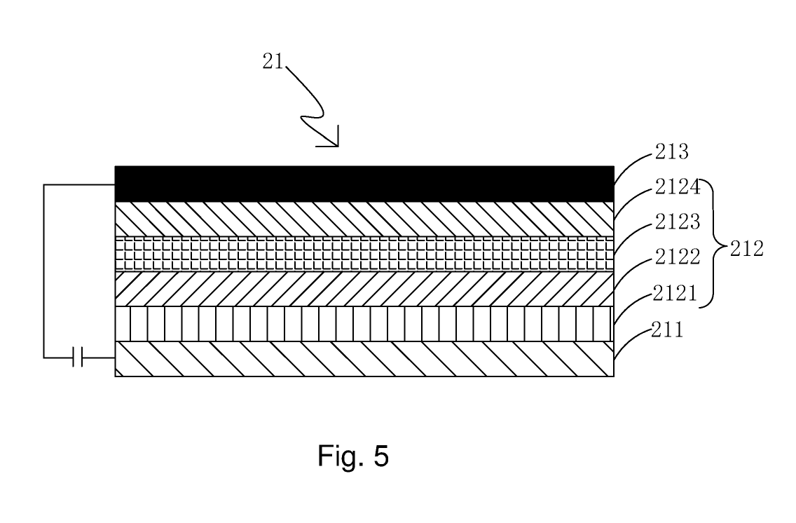

Selectably, referring to FIG. 5, the blue light emitting layer 212 is an OLED light emitting layer or a (Quantum dots Light-emitting Diodes) QLED light emitting layer, which specifically comprises: a hole injecting layer 2121 located on the anode 211, a hole transporting layer 2122 located on the hole injecting layer 2121, an emission layer 2123 located on the hole injecting layer 2122, and an electron transporting layer 2124 located on the emission layer 2123. The electron and the hole respectively migrate from the cathode 213 and the anode 211 to the emission layer 2123 to excite the emission layer 2123 to emit blue light.

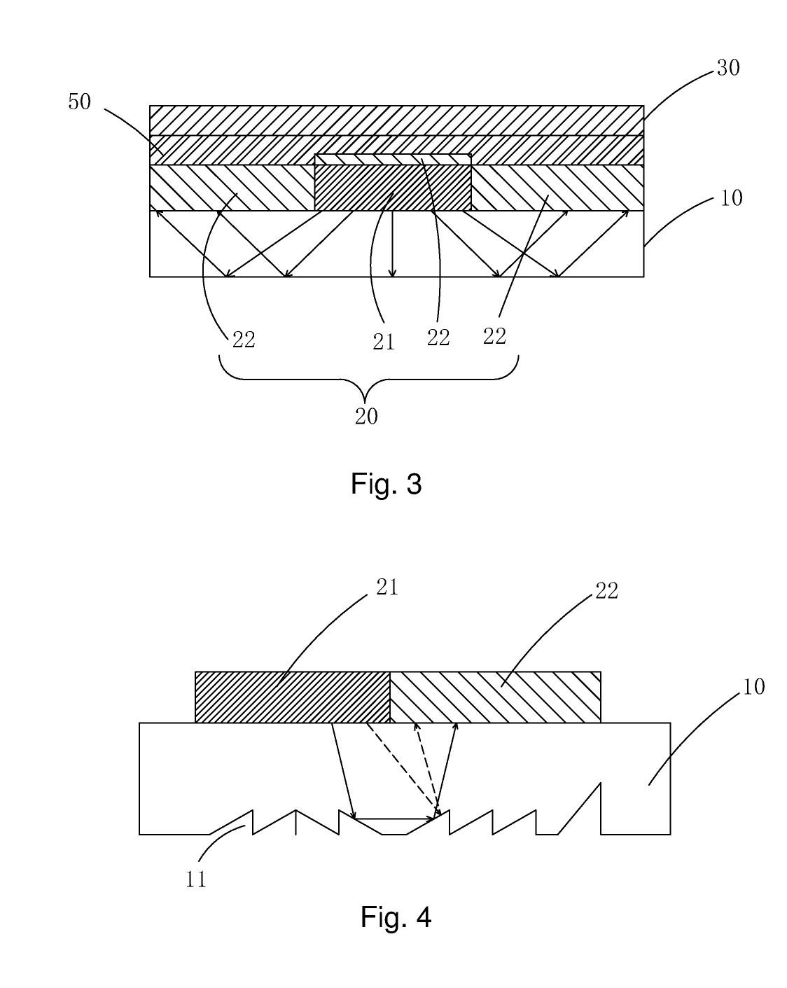

Selectably, referring to FIG. 3, in the second embodiment of the present invention, the photoluminescence layer 22 is not merely located at the two sides of the electroluminescence layer 21 but also located on the top of the electroluminescence layer 21, and a film thickness of the photoluminescence layer 22 located at the top of the electroluminescence layer 21 is smaller than a film thickness of the photoluminescence layer 22 located at the two sides of the electroluminescence layer 21; a flat layer 50 is further located between the light emitting layer 20 and the light filtering layer 30. Compared with the first embodiment, the blue light conversion efficiency in the second embodiment is higher, and meanwhile, the added flat layer 50 can make the element performance more uniform and more stable, and can protect the light emitting layer 20 from damage in the following processes.

Specifically, the light filtering layer 30 comprises: a red filter layer, a blue filter layer and a green filter layer, and each sub pixel corresponds to a light filter layer 30 of one color, and three sub pixels corresponding to the light filter layers of three colors construct one display pixel; a black matrix is located among the light filter layers 30 of adjacent sub pixels, and with the light filtering layer 30, the white light emitted by the light emitting layer 20 is converted in to red, green, blue, three primary colors to achieve the color display, and the black matrix located among the light filter layers 30 of the adjacent sub pixels can prevent the interference of the lights of the adjacent sub pixels.

Significantly, the cathode 213 can be a metal silver thin layer, a graphene transparent conductive film or a metal nano mesh structure. The reflectivity and the transmissivity of the cathode 213 for the blue light can be controlled by changing the thickness of the metal silver thin layer or the graphene transparent conductive film, or changing the metal nano mesh design. The electroluminescence layer 21 illuminates the light from two sides, the cathode 213 and the anode 211, and the illuminating efficiency at the side of the cathode 213 is smaller than the illuminating efficiency at the side of the anode 211.

Furthermore, by adjusting the mixing ratio of the red quantum dots material and the green quantum dots material in the photoluminescence layer 22, the light emitted from the element can be adjusted, and meanwhile, the occupied ratio of the electroluminescence layer 21 and the photoluminescence layer 22 in the light emitting layer 20 can be adjusted according to the requirement.

Besides, referring to FIG. 4, the zigzag structures formed by the cross sections of the respective grooves 11 are different. By adjusting the angles of the zigzag structure formed by the cross sections of the respective grooves 11, the reflection direction and the transmission distance of the blue light emitted by the electroluminescence layer 21 are controlled to make the blue light emitted by the electroluminescence layer 21 irradiate on the corresponding photoluminescence layer 22 to excite the photoluminescence layer 22 to emit the light. In comparison with prior art, the present invention directly guides the blue light from the anode 211, and illuminates the same through the light guide substrate 10 and the photoluminescence layer 22 without passing through many film layers, and the light efficiency is greatly raised.

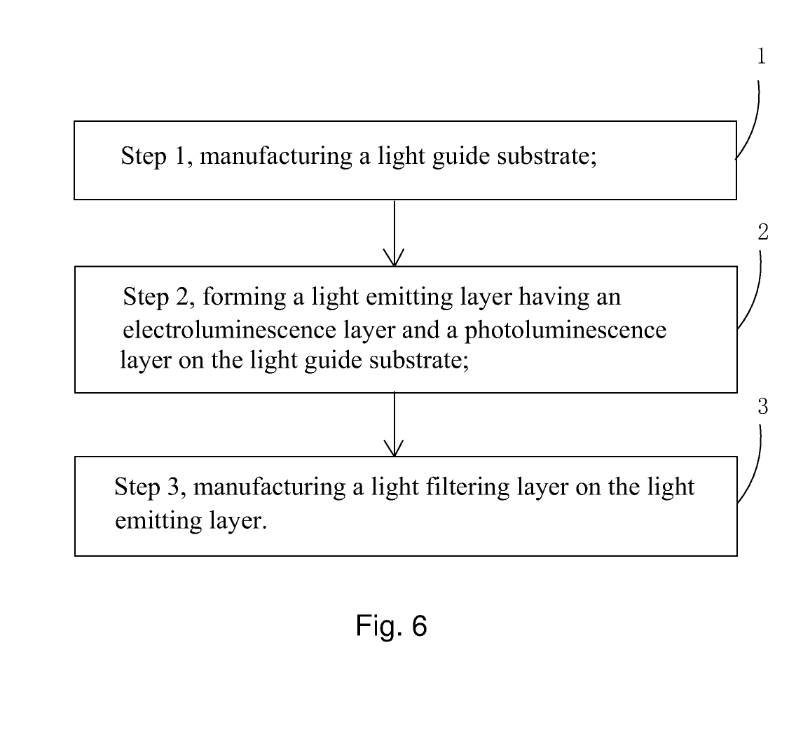

Please refer to FIG. 6, the present invention further comprises a manufacture method of an electroluminescence and photoluminescence mixed display element, comprising steps of:

step 1, providing a substrate, and forming a plurality of grooves 11 extending along the same direction on a lower substrate of the substrate, and transversal cross sections of the plurality of grooves 11 appear to be aligned in an zigzag, and the lower surface of the light guide substrate is coated with a reflective film to form a light guide substrate 10.

Specifically, the plurality of grooves 11 on the light guide substrate 10 are manufactured with the imprint technology, and the plurality of grooves 11 are employed to directionally guide the light.

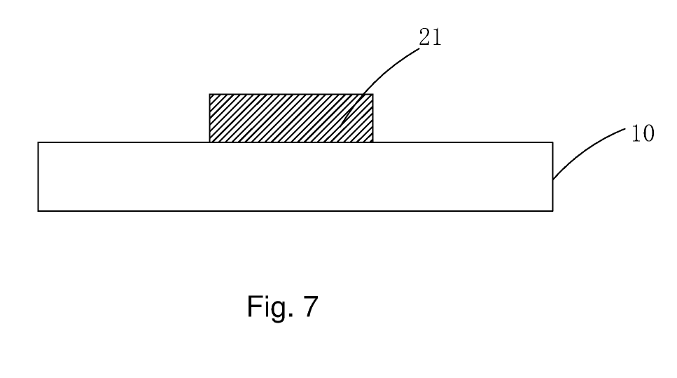

step 2, referring to FIG. 7, dividing the light guide substrate 10 into a plurality of sub pixel regions aligned in array, and a short side direction of the sub pixel region and an extension direction of the grooves 11 are the same, and forming a light emitting layer 20 on the respective sub pixel regions;

the light emitting layer 20 comprises: an electroluminescence layer 21 and a photoluminescence layer 22 located at two sides of the electroluminescence layer 21, which are sequentially formed;

the electroluminescence layer 21 comprises: an anode 211 located on the light guide substrate 10, a blue light emitting layer 212 located on the anode 211, and a cathode 213 located on the blue light emitting layer 212;

the anode 211 is a transparent electrode, and the cathode 213 is a transflective electrode;

the photoluminescence layer 22 comprises red quantum dots material and green quantum dots material.

Selectably, referring to FIG. 5, the blue light emitting layer 212 is an OLED light emitting layer or a (Quantum dots Light-emitting Diodes) QLED light emitting layer, which specifically comprises: a hole injecting layer 2121 located on the anode 211, a hole transporting layer 2122 located on the hole injecting layer 2121, an emission layer 2123 located on the hole injecting layer 2122, and an electron transporting layer 2124 located on the emission layer 2123. The electron and the hole respectively migrate from the cathode 213 and the anode 211 to the emission layer 2123 to excite the emission layer 2123 to emit blue light.

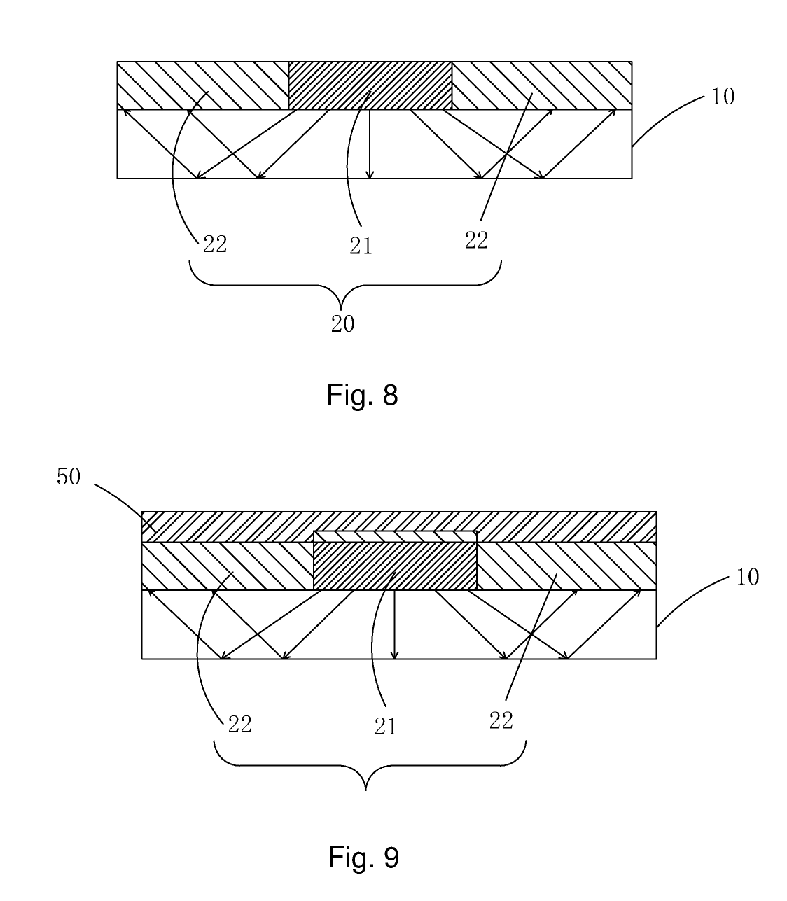

Selectably, referring to FIG. 8, in the first embodiment of the present invention, the step 2 comprises: first, forming the electroluminescence layer 21 on the light guide substrate 10, and then, forming the photoluminescence layer 22 at two sides of the electroluminescence layer 21 by a method of coating specific regions.

Selectably, referring to FIG. 9, in the second embodiment of the present invention, the step 2 comprises: first, forming the electroluminescence layer 21 on the light guide substrate 10, and then, forming the photoluminescence layers 22 at the two sides and a top of the electroluminescence layer 21 by a method of full coating, and a film thickness of the photoluminescence layer 22 located at a top of the electroluminescence layer 21 is smaller than a film thickness of the photoluminescence layer 22 located at the two sides of the electroluminescence layer 21, and then, forming a flat layer 50 on the light emitting layer 20. Compared with the first embodiment, the blue light conversion efficiency in the second embodiment is higher, and meanwhile, the added flat layer 50 can make the element performance more uniform and more stable, and can protect the light emitting layer 20 from damage in the following processes.

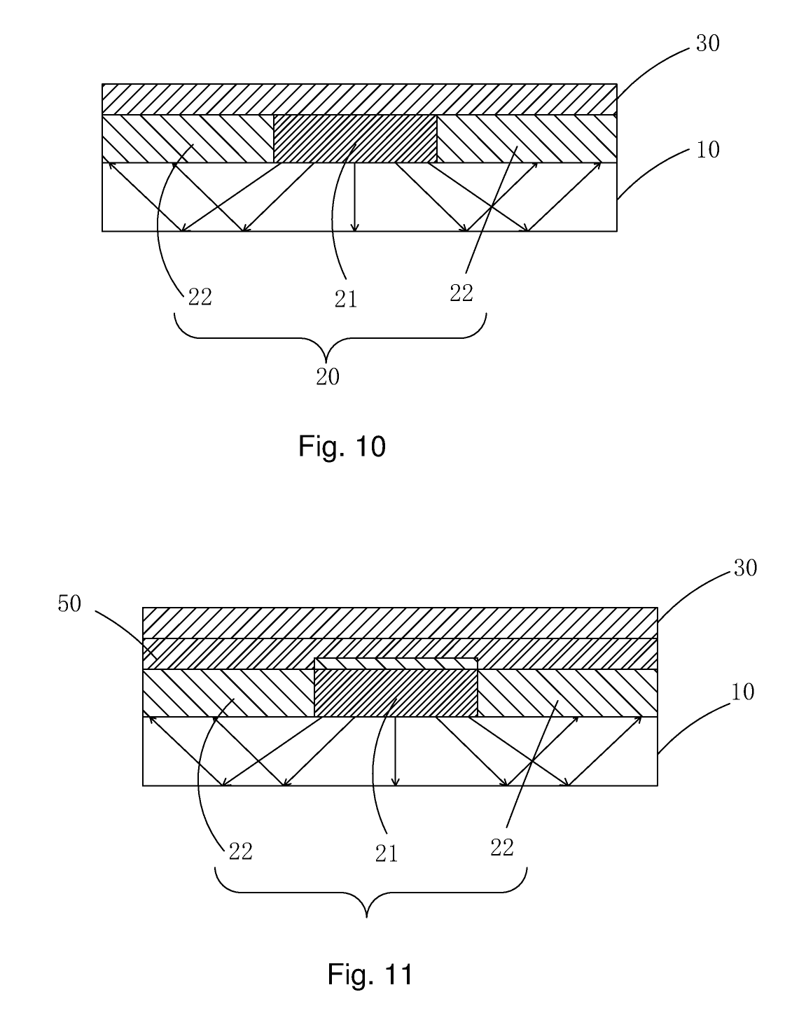

step 3, referring to FIG. 10 or FIG. 11, forming a light filtering layer 30 on the light emitting layer 20, and forming a plurality of sub pixels aligned in array on the light guide substrate 10 to manufacture the electroluminescence and photoluminescence mixed display element.

Specifically, the color display process of the electroluminescence and photoluminescence mixed display element is: the drive voltage is applied to the electroluminescence layer 21 to excite the electroluminescence layer 21 to emit the blue light, and the blue light emitted by the electroluminescence layer 21 is respectively illuminated through two directions of the anode 211 and the cathode 213, and the blue light illuminated through the anode 211 is reflected by the light guide substrate 10 onto the photoluminescence layer 22 to excite the photoluminescence layer 22 to emit red light and green light, and red light and the green light emitted by the photoluminescence layer 22 and the blue light emitted by the electroluminescence layer 21 are mixed to form white light, and the white light is filtered by the light filtering 30 to achieve color display.

Specifically, the light filtering layer 30 comprises: a red filter layer, a blue filter layer and a green filter layer, and each sub pixel corresponds to a light filter layer 30 of one color, and three sub pixels corresponding to the light filter layers of three colors construct one display pixel; a black matrix is located among the light filter layers 30 of adjacent sub pixels, and with the light filtering layer 30, the white light emitted by the light emitting layer 20 is converted in to red, green, blue, three primary colors to achieve the color display, and the black matrix located among the light filter layers 30 of the adjacent sub pixels can prevent the interference of the lights of the adjacent sub pixels.

Significantly, the cathode 213 can be a metal silver thin layer, a graphene transparent conductive film or a metal nano mesh structure. The reflectivity and the transmissivity of the cathode 213 for the blue light can be controlled by changing the thickness of the metal silver thin layer or the graphene transparent conductive film, or changing the metal nano mesh design. The electroluminescence layer 21 illuminates the light from two sides, the cathode 213 and the anode 211, and the illuminating efficiency at the side of the cathode 213 is smaller than the illuminating efficiency at the side of the anode 211.

Furthermore, by adjusting the mixing ratio of the red quantum dots material and the green quantum dots material in the photoluminescence layer 22, the light emitted from the element can be adjusted, and meanwhile, the occupied ratio of the electroluminescence layer 21 and the photoluminescence layer 22 in the light emitting layer 20 can be adjusted according to the requirement.

Besides, referring to FIG. 4, the zigzag structures formed by the cross sections of the respective grooves 11 are different. By adjusting the angles of the zigzag structure formed by the cross sections of the respective grooves 11, the reflection direction and the transmission distance of the blue light emitted by the electroluminescence layer 21 are controlled to make the blue light emitted by the electroluminescence layer 21 irradiate on the corresponding photoluminescence layer 22 to excite the photoluminescence layer 22 to emit the light. In comparison with prior art, the present invention directly guides the blue light from the anode 211, and illuminates the same through the light guide substrate 10 and the photoluminescence layer 22 without passing through many film layers, and the light efficiency is greatly raised.

In conclusion, the electroluminescence and photoluminescence mixed display element provided by the present invention comprises: a light guide substrate, a light emitting layer located on the light guide substrate, a light filtering layer located on the light emitting layer, wherein the light emitting layer comprises an electroluminescence layer and a photoluminescence layer, and the cathode of the electroluminescence layer is a transflective electrode, and the anode is a transparent electrode, and the electroluminescence layer can illuminates the blue light from two sides, the cathode and the anode, and the blue light illuminated from the anode is directionally guided by the light guide substrate and is reflected onto the photoluminescence layer to excite the photoluminescence layer emit the red light and the green light, and the red light and the green light emitted by the photoluminescence layer and the blue light emitted by the electroluminescence layer are mixed to form white light, and the white light is filtered by the light filtering layer to achieve color display, which can raise the light efficiency, and raise the color gamut of the display element, and increase the color reduction ability to promote the product quality. The present invention further provides a manufacture method of an electroluminescence and photoluminescence mixed display element, which can raise the light efficiency, and raise the color gamut of the display element, and increase the color reduction ability to promote the product quality.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. An electroluminescence and photoluminescence mixed display element, comprising a light guide substrate, and a plurality of sub pixels aligned in array on the light guide substrate;
each sub pixel comprises: a light emitting layer located on the light guide substrate, and a light filtering layer located on the light emitting layer;
a lower substrate of the light guide substrate is formed with a plurality of grooves extending along a short side direction of the sub pixel, and transversal cross sections of the plurality of grooves appear to be aligned in an zigzag, and the lower surface of the light guide substrate is coated with a reflective film;
the light emitting layer comprises: an electroluminescence layer and a photoluminescence layer located at two sides of the electroluminescence layer;
the electroluminescence layer comprises: an anode located on the light guide substrate, a blue light emitting layer located on the anode, and a cathode located on the blue light emitting layer;
the anode is a transparent electrode, and the cathode is a transflective electrode;
the photoluminescence layer comprises red quantum dots material and green quantum dots material;
blue light emitted by the electroluminescence layer is respectively illuminated through two directions of the anode and the cathode, and the blue light illuminated through the anode is reflected by the light guide substrate onto the photoluminescence layer to excite the photoluminescence layer to emit red light and green light, and red light and the green light emitted by the photoluminescence layer and the blue light emitted by the electroluminescence layer are mixed to form white light, and the white light is filtered by the light filtering layer to achieve color display.

2. The electroluminescence and photoluminescence mixed display element according to claim 1, wherein the blue light emitting layer is an OLED light emitting layer or a QLED light emitting layer;
the blue light emitting layer comprises: a hole injecting layer located on the anode, a hole transporting layer located on the hole injecting layer, an emission layer located on the hole injecting layer, and an electron transporting layer located on the emission layer.

3. The electroluminescence and photoluminescence mixed display element according to claim 1, wherein the cathode is a metal silver thin layer, a graphene transparent conductive film or a metal nano mesh structure.

4. The electroluminescence and photoluminescence mixed display element according to claim 1, wherein the light emitting layer further comprises a photoluminescence layer located at a top of the electroluminescence layer, and a film thickness of the photoluminescence layer located at a top of the electroluminescence layer is smaller than a film thickness of the photoluminescence layer located at the two sides of the electroluminescence layer;
a flat layer is further located between the light emitting layer and the light filtering layer.

5. The electroluminescence and photoluminescence mixed display element according to claim 1, wherein the light filtering layer comprises: a red filter layer, a blue filter layer and a green filter layer, and each sub pixel corresponds to a light filtering layer of one color, and three sub pixels corresponding to the light filtering layers of three colors construct one display pixel;
a black matrix is located among the light filtering layers of adjacent sub pixels.

6. A manufacture method of an electroluminescence and photoluminescence mixed display element, comprising steps of:
step 1, providing a substrate, and forming a plurality of grooves extending along the same direction on a lower substrate of the substrate, and transversal cross sections of the plurality of grooves appear to be aligned in an zigzag, and the lower surface of the light guide substrate is coated with a reflective film to form a light guide substrate;
step 2, dividing the light guide substrate into a plurality of sub pixel regions aligned in array, and a short side direction of the sub pixel region and an extension direction of the grooves are the same, and forming a light emitting layer on the respective sub pixel regions;
the light emitting layer comprises: an electroluminescence layer and a photoluminescence layer located at two sides of the electroluminescence layer, which are sequentially formed;
the electroluminescence layer comprises: an anode located on the light guide substrate, a blue light emitting layer located on the anode, and a cathode located on the blue light emitting layer;
the anode is a transparent electrode, and the cathode is a transflective electrode;
the photoluminescence layer comprises red quantum dots material and green quantum dots material;
step 3, forming a light filtering layer on the light emitting layer, and forming a plurality of sub pixels aligned in array on the light guide substrate to manufacture the electroluminescence and photoluminescence mixed display element;
blue light emitted by the electroluminescence layer is respectively illuminated through two directions of the anode and the cathode, and the blue light illuminated through the anode is reflected by the light guide substrate onto the photoluminescence layer to excite the photoluminescence layer to emit red light and green light, and red light and the green light emitted by the photoluminescence layer and the blue light emitted by the electroluminescence layer are mixed to form white light, and the white light is filtered by the light filtering layer to achieve color display.

7. The manufacture method of the electroluminescence and photoluminescence mixed display element according to claim 6, wherein the blue light emitting layer is an OLED light emitting layer or a QLED light emitting layer;
the blue light emitting layer comprises: a hole injecting layer located on the anode, a hole transporting layer located on the hole injecting layer, an emission layer located on the hole injecting layer, and an electron transporting layer located on the emission layer.

8. The manufacture method of the electroluminescence and photoluminescence mixed display element according to claim 6, wherein the step 2 comprises: first, forming the electroluminescence layer on the light guide substrate, and then, forming the photoluminescence layer at two sides of the electroluminescence layer by a method of coating specific regions.

9. The manufacture method of the electroluminescence and photoluminescence mixed display element according to claim 6, wherein the step 2 comprises: first, forming the electroluminescence layer on the light guide substrate, and then, forming the photoluminescence layers at the two sides and a top of the electroluminescence layer by a method of full coating, and a film thickness of the photoluminescence layer located at a top of the electroluminescence layer is smaller than a film thickness of the photoluminescence layer located at the two sides of the electroluminescence layer, and then, forming a flat layer on the light emitting layer.

10. The manufacture method of the electroluminescence and photoluminescence mixed display element according to claim 6, wherein the light filtering layer comprises: a red filter layer, a blue filter layer and a green filter layer, and each sub pixel corresponds to a light filtering layer of one color, and three sub pixels corresponding to the light filtering layers of three colors construct one display pixel;
a black matrix is located among the light filtering layers of adjacent sub pixels.

11. An electroluminescence and photoluminescence mixed display element, comprising a light guide substrate, and a plurality of sub pixels aligned in array on the light guide substrate;
each sub pixel comprises: a light emitting layer located on the light guide substrate, and a light filtering layer located on the light emitting layer;
a lower substrate of the light guide substrate is formed with a plurality of grooves extending along a short side direction of the sub pixel, and transversal cross sections of the plurality of grooves appear to be aligned in an zigzag, and the lower surface of the light guide substrate is coated with a reflective film;
the light emitting layer comprises: an electroluminescence layer and a photoluminescence layer located at two sides of the electroluminescence layer;
the electroluminescence layer comprises: an anode located on the light guide substrate, a blue light emitting layer located on the anode, and a cathode located on the blue light emitting layer;
the anode is a transparent electrode, and the cathode is a transflective electrode;
the photoluminescence layer comprises red quantum dots material and green quantum dots material;
blue light emitted by the electroluminescence layer is respectively illuminated through two directions of the anode and the cathode, and the blue light illuminated through the anode is reflected by the light guide substrate onto the photoluminescence layer to excite the photoluminescence layer to emit red light and green light, and red light and the green light emitted by the photoluminescence layer and the blue light emitted by the electroluminescence layer are mixed to form white light, and the white light is filtered by the light filtering layer to achieve color display;
wherein the blue light emitting layer is an OLED light emitting layer or a QLED light emitting layer;
the blue light emitting layer comprises: a hole injecting layer located on the anode, a hole transporting layer located on the hole injecting layer, an emission layer located on the hole injecting layer, and an electron transporting layer located on the emission layer;
wherein the cathode is a metal silver thin layer, a graphene transparent conductive film or a metal nano mesh structure.

12. The manufacture method of the electroluminescence and photoluminescence mixed display element according to claim 11, wherein the light emitting layer further comprises a photoluminescence layer located at a top of the electroluminescence layer, and a film thickness of the photoluminescence layer located at a top of the electroluminescence layer is smaller than a film thickness of the photoluminescence layer located at the two sides of the electroluminescence layer;
a flat layer is further located between the light emitting layer and the light filtering layer.

13. The electroluminescence and photoluminescence mixed display element according to claim 11, wherein the light filtering layer comprises: a red filter layer, a blue filter layer and a green filter layer, and each sub pixel corresponds to a light filtering layer of one color, and three sub pixels corresponding to the light filtering layers of three colors construct one display pixel;
a black matrix is located among the light filtering layers of adjacent sub pixels.
